(19) United States
(12) Patent Application Publication
(10) Pub. No.: US 2013/0265076 A1
(43) Pub. Date: Oct. 10, 2013

(54) ADAPTER BOARD AND DC POWER SUPPLY TEST SYSTEM USING SAME

(71) Applicants: HONG FU JIN PRECISION INDUSTRY (ShenZhen) CO., LTD., (US); HON HAI PRECISION INDUSTRY CO., LTD., (US)

(72) Inventors: YA-JUN PAN, Shenzhen (CN); TING GE, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/854,986

(22) Filed: Apr. 2, 2013

(30) Foreign Application Priority Data
Apr. 10, 2012 (CN) 201210102802.4

(51) Int. Cl. G01R 31/40; H05K 1/02; H05K 1/18

(52) U.S. Cl. CPC G01R 31/40; H05K 1/181; H05K 1/0213
USPC 324/756.07; 361/760; 324/149

(57) ABSTRACT

An adapter board includes a PCB, a first gold finger mounted on the PCB, and a plurality of first connectors mounted on the PCB. The first gold finger includes a first ground pin and a plurality of power pin groups. Each first connector includes a load connection pin and a second ground pin electronically connected to the first ground pin, the load connecting pin of each first connector is electronically connected to a load, a oscilloscope, and a corresponding power pin group.

### BACKGROUND

1. Technical Field

The exemplary disclosure generally relates to adapter boards, and particularly to an adapter board used in direct current (DC) power supply test system.

2. Description of Related Art

A peripheral component interconnect extended (PCI-X) expansion card is capable of connecting PCI-X cards to a motherboard. One PCI-X expansion card can connect two or three PCI-X cards to the motherboard. The PCI-X expansion card includes a voltage conversion circuit and a plurality of slots for the insertion of the PCI-X cards.

The voltage output terminals of the voltage conversion circuit are electronically connected to the slots via a plurality of copper lines printed on a printed circuit board (PCB). When functionality of the voltage conversion circuit is tested, a test probe is positioned onto the output terminal of the voltage conversion circuit to obtain the corresponding output voltage. Since there is a certain distance between the voltage output terminal and the corresponding slot, when the voltage flows from the copper line from the voltage terminal to the slot, a voltage drop will be generated. That is, a voltage at the voltage output terminal (which is a test point) is larger than a voltage at the corresponding power pin (which is a load driving point) of the slot, which will decrease accuracy of the test.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the disclosure.

FIG. 1 shows a block diagram of an exemplary embodiment of a DC power test system for testing an expansion card.

FIG. 2 shows a schematic diagram of an exemplary embodiment of an adapter board of the DC power test system shown in FIG. 1.

FIG. 3 shows a schematic diagram of the DC power test system shown in FIG. 1.

### DETAILED DESCRIPTION

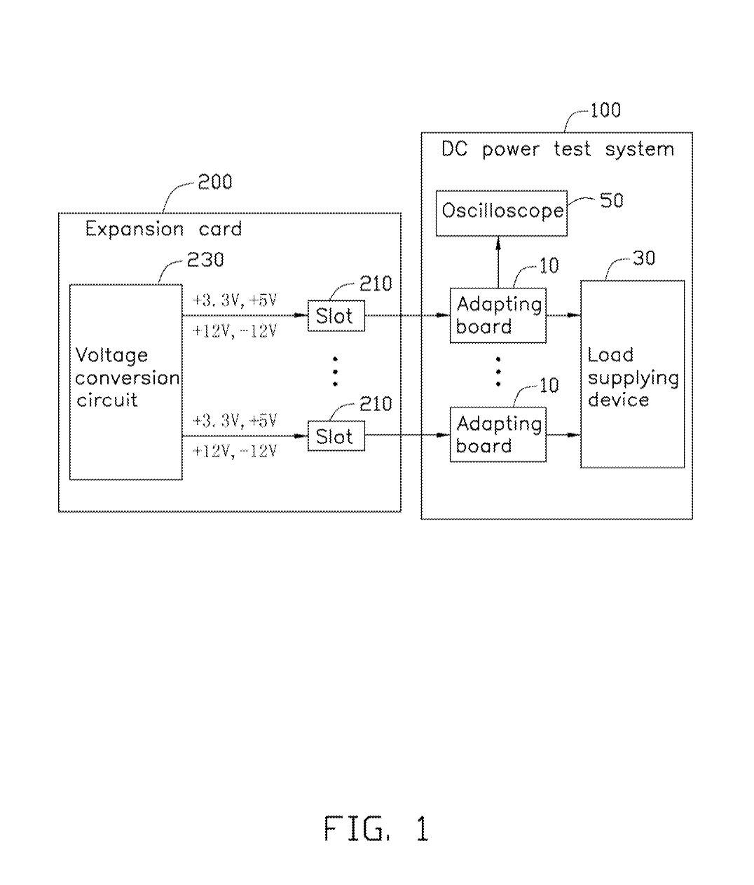

FIG. 1 shows a block diagram of an exemplary embodiment of a DC power test system 100 for testing an expansion card 200. The expansion card 200 can be PCI series expansion card, such as a peripheral component interconnect (PCI) expansion card, a PCI-X expansion card, or a peripheral component interconnect-express (PCI-E) expansion card, for example. The expansion card 200 includes a plurality of slots 210 and a voltage conversion circuit 230. Each slot 230 includes a plurality of +5V power pins, a plurality of +3.3V power pins, a plurality of +12V power pins, and a plurality of −12V power pins. The voltage conversion circuits 230 output a plurality of output powers, such as +5V output power, +3.3V output power, +12V output power, and −12V output power corresponding to the power pins of each slot 230. The DC power test system 100 is used to test voltage and current of the output power. The DC power test system 100 includes a plurality of adapter boards 10, a load supplying device 30, and an oscilloscope 50.

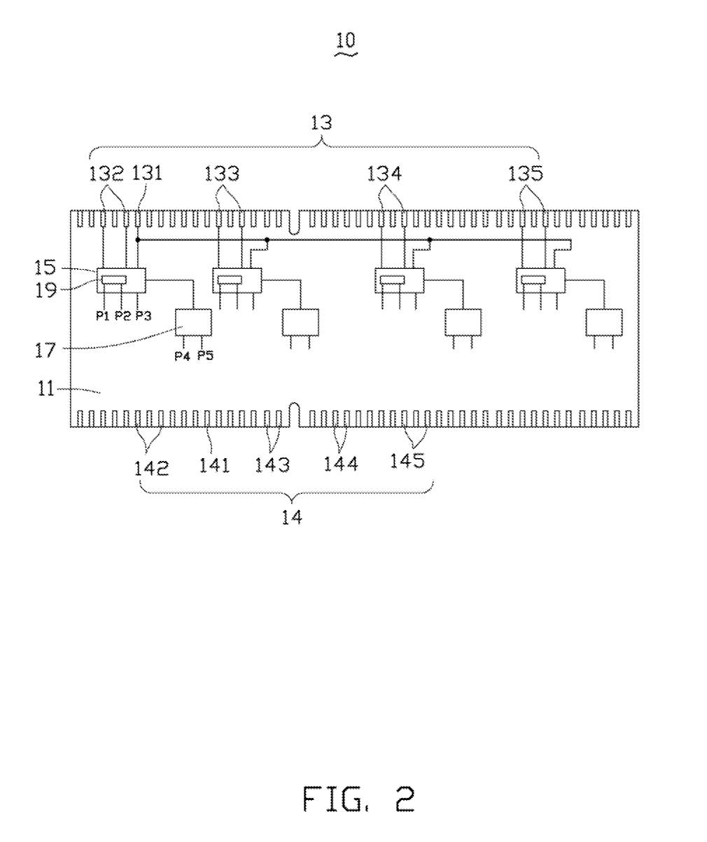

FIG. 2 shows a schematic diagram of an exemplary embodiment of an adapter board 10 of the DC power test system shown 100 in FIG. 1. The adapter boards 10 are plugged in the slots 210 respectively. Each adapter board 10 includes a PCB 11, a first gold finger 13 positioned on one end of the PCB, a plurality of first connectors 15 electronically connected to the first gold finger 13, a plurality of second connectors 17 electronically connected to the first connectors 15 respectively, and a plurality of current detectors 19 positioned in the first connector 14 respectively. The first connectors 13 and the second connectors 15 are positioned on the PCB 11.

The first gold finger 13 mates with and is plugged into one of the slots 210. The first gold finger 13 includes a first ground pin 131 and a plurality of power pin groups. For example, the first gold finger 13 includes a group of +5V power pins, a group of +3.3V power pins, a group of +12V power pins, and a group of −12V power pins. Each power pin group includes at least one power pin. In the exemplary embodiment, the first gold finger 13 includes two +5V power pins 132, two +3.3V power pins 133, two +12V power pins 134, and two −12V power pins 135.

Each first connector 15 is electronically connected to a corresponding power pin group and the first ground pin 131. Each first connector 15 includes a load connection pin P1, a current detection pin P2, and a second ground pin P3. The load connection pin P1 is electronically connected to each power pin of the corresponding power pin group. The voltage of the load connection pin P1 is equal to the voltage of the power pins connected to the load connection pin P1. The second ground pin P3 is electronically connected to the first ground pin 131 of the first gold finger 13. The current detection pin P2 is electronically connected to the load connection pin P1 via a corresponding current detector 19. The current detector 19 detects a current flowing through the load connection pin P1, that is, a current output from the power pin group connected to the load connection pin P1, and outputs the detected current to the current detection pin P2.

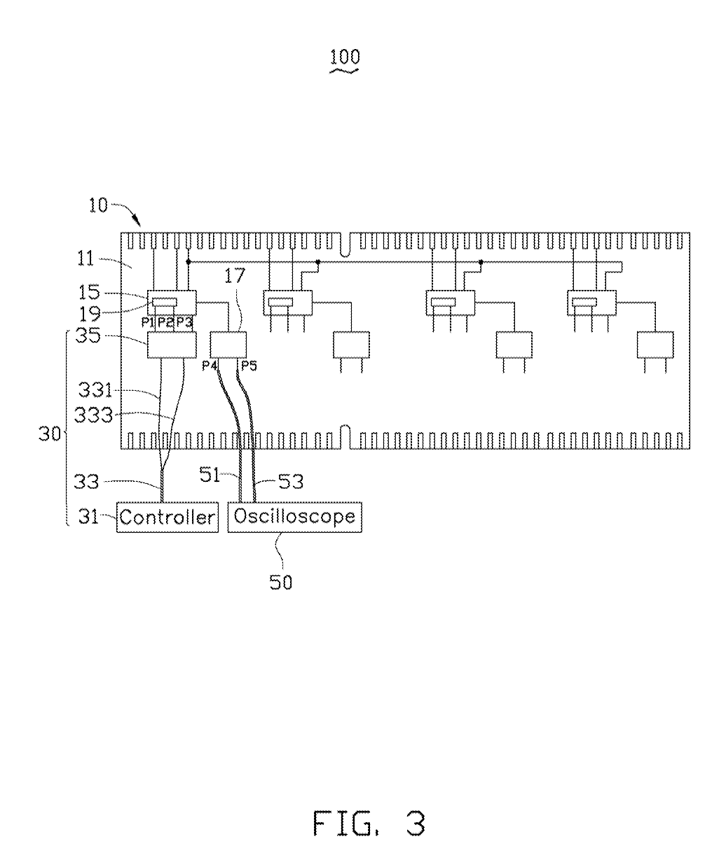

FIG. 3 shows a schematic diagram of the DC power test system 100 shown in FIG. 1. Each second connector 17 includes an output pin P4, and a third ground pin P5. Each output pin P4 and each third ground pin P5 are connected to the load connection pin P1 and the second ground pin P3 of a corresponding first connector 15 respectively (the connection circuit is not shown in FIGS. 1-3). The oscilloscope 50 is electronically connected to the output pin P4 and the third ground pin P5 of one of the second connectors 17 via two cables 51 and 53 respectively. The oscilloscope 50 detects and displays the voltage of the load connection pin P1, that is, the voltage of the group of power pins of the slot 210 mating with the adapter board 10.

The load supplying device 30 supplies load to each output power of the voltage conversion circuit 230 via the adapter boards 10. The load supplying device 30 includes a controller 31, a plurality of detection cable groups 33, and a plurality of third connectors 35 connected to the detection cable groups 33 respectively. Each detection cable group 33 includes a load cable 331 and a current detection cable 333 both of which are electronically connected to the controller 31. The third connectors 35 mate with the first connectors 15, which are connected to the same power pins. For example, one of the third connectors 35 is electronically connected to the first connector 15 connected to the +5V power pin 132 of one of the adapter boards 10; another one of the third connectors 35 is electronically connected to the first connector 15 connected to the +5V power pin 132 of another one of the adapter board 10. So that each load cable 331 is electronically connected to the load connection pin P1 of one of the first connectors 15 via a corresponding third connector 35; and each current detection cable 333 is electronically connected to the current detection pin P2 of one of the first connectors 15 via a the corresponding third connector 35. The load cable 331 supplies a load (not shown) to the load connection pin P1, to simulate an insertion of a PCI series card. The current detection cable 333 receives the current detected by the current detector 19 via the current detection pin P2, and outputs the received current to the controller 31.

Each detection cable group 33 transmits a current of one output power divided by a corresponding slot 210, the controller 31 statistics the current transmitted by the plurality of detection cable groups 33, thereby obtaining a total current of the corresponding output power. The controller 31 adjusts the load of each load cable 331, to equate the detected total current of the corresponding output power to a predetermined current value. The predetermined current value is a value of an output current of the corresponding output power when the expansion card 200 is in use.

For example, in use, when the load supplying device 30 detects the current of the +5V output power output by the voltage conversion circuit 230, the plurality of adapter boards 10 are plugged into the slots 210 respectively, each third connector 35 is electronically connected to the corresponding first connector 15 connected to the +5V power pin 132. At this time, the plurality of slots 210 divides the current of the +5V output power output by the voltage conversion circuit 230, and the group of +5V power pins of each slot 210 obtain a part of the current of the +5V output power. Each current detection cable 333 receives the current divided by the corresponding slot 210 via the first connector 15 of the adapter board 10; the controller 31 obtains the total current via the current detection cables 333, and compares the total current with the predetermined current value. If the total current does not equal to the predetermined current value, the controller 31 adjusts the load of each load cable 331 until the total current equals to the predetermined current value. After that, the oscilloscope 50 detects and displays the voltage of the load connection pin P1 of the first connector 13 via the second connector 17. Such that a user can easily know whether the voltage of the +5V output power is equal to +5V. Since the first connector 15 is connected to the output power of the voltage conversion circuit 230 via the corresponding slot 210. In addition, both the load cable 331 and the oscilloscope 50 are connected to the load connection pin P1 of the connector 15, a load driving point (that is the node between the load cable 331 and the load connection pin P1) and a test point (that is the node between the oscilloscope 50 and the load connection pin P1) are both positioned on the connection pin P1. Thus a voltage of the load driving point is equal to a voltage of the test point, which can increase the accuracy of test results.

PCI series bus configuration has a plurality of different versions, for example, PCI-X bus configuration has 1.0 version and 2.0 version and a 1.0 version slot has a pinout configuration that different from the pinout configuration of a 2.0 version slot. Therefore, the exemplary embodiment matches different slots with different versions, as each adapter board 10 further includes a second gold finger 14 (shown in FIG. 2). The second gold finger 14 is positioned to the other end of the PCB 11 opposite to the first gold finger 13. The second gold finger 14 has a pinout configuration that is different from the pinout configuration of the first gold finger 13. The second gold finger 14 is plugged into the slot 210, which has the same pinout configuration as the pinout configuration of the second gold finger 14.

The second gold finger 14 has the same function as the function of the first gold finger 14. The second gold finger 14 includes a plurality of power pin groups, and a fourth ground pin 141. For example, the second gold finger 141 includes two +5V power pins 142, two +3.3V power pins 143, two +12V power pins 144, and two −12V power pins 145. Each power pin group is connected to the load connection pin P1 of one of the first connectors 15 (the connection circuits are not shown). The fourth ground pin 141 is electronically connected to the second ground pin P3 of the first connector 15.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An adapter board, comprising:
a printed circuit board (PCB);
a first gold finger mounted on the PCB and mating with a slot, the first gold finger comprising a first ground pin and a plurality of power pin groups, the first ground pin and the plurality of power pin groups electronically connected to the slot;
a plurality of first connectors mounted on the PCB, each first connector comprising a load connection pin and a second ground pin electronically connected to the first ground pin, the load connecting pin of each first connector electronically connected to a corresponding power pin group, a load, and an oscilloscope.

2. The adapter board of claim 1, further comprising a plurality of second connectors, wherein each second connector comprising an output pin electronically connected to the load connection pin, and a third ground pin electronically connected to the second ground pin, the output pin and the third ground pin are electronically connected to the oscilloscope.

3. The adapter board of claim 1, further comprising a plurality of current detector mounted into the plurality of first connectors respectively, wherein each first connector further comprises a current detection pin electronically connected to the load connection pin via a corresponding current detector, the current detector detects current flowing to the load connection pin, and outputs a detected current to the current detection pin.

4. The adapter board of claim 1, further comprising a second gold finger mating with another slot, wherein the second gold finger comprises a fourth ground pin and a plurality of power pin groups, the fourth ground pin is electronically connected to the second ground pin, each power pin group of the second gold finger is electronically connected to the load connection pin of a corresponding first connector.

5. The adapter board of claim 1, wherein the first gold finger is plugged into a slot of one of a peripheral component interconnect (PCI) expansion card, a peripheral component interconnect extended (PCI-X) expansion card, and a peripheral component interconnect-express (PCI-E) expansion card.

6. A direct current (DC) power test system, comprising:
at least one adapter board, each adapter board comprising:
a printed circuit board (PCB);
a first gold finger mounted on the PCB and mating with a slot, the first gold finger comprising a first ground pin and a plurality of power pin groups, the first ground pin and the plurality of power pin groups electronically connected to the slot;
a plurality of first connectors mounted on the PCB, each first connector comprising a load connection pin and a second ground pin electronically connected to the first ground pin, the load connecting pin of each first connector electronically connected to a corresponding power pin group;
a load supplying device electronically connected to the load connection pin of the first connectors that are connected to the same power pin group of the at least one adapter board, the load supplying device supplying a load to each load connection pin; and
a oscilloscope electronically connected to the load connection pin and the second ground pin of one of the plurality of first connectors, to detect and display a voltage on the load connection pin.

7. The DC power test system of claim 6, wherein further comprising a plurality of second connectors, wherein each second connector comprising an output pin electronically connected to the load connection pin, and a third ground pin electronically connected to the second ground pin, the output pin and the third ground pin are electronically connected to the oscilloscope.

8. The DC power test system of claim 6, further comprising a plurality of current detector mounted into the plurality of first connectors respectively, wherein each first connector further comprises a current detection pin electronically connected to the load connection pin via a corresponding current detector, the current detector detects the current flowing to the load connection pin, and outputs a detected current to the current detection pin.

9. The DC power test system of claim 6, further comprising a second gold finger mating with another slot, wherein the second gold finger comprises a fourth ground pin and a plurality of power pin groups, the fourth ground pin is electronically connected to the second ground pin, each power pin group of the second gold finger is electronically connected to the load connection pin of a corresponding first connector.

10. The DC power test system of claim 6, wherein the first gold finger is plugged into a slot of one of a PCI expansion card, a PCI-X expansion card, and a PCI-E expansion card.

11. The DC power test system of claim 8, wherein the load supplying device comprises a controller, at least one third connectors, and a plurality of detection cable groups, the at least one third connectors are electronically connected to the first connectors that are connected to the same power pins of the at least one adapter board; each detection cable group comprises a load cable and a current detection cable that are connected to the controller, each load cable is electronically connected to the load connection pin via a corresponding third connector, to supply the load to the load connection pin under the control of the controller; the current detection cable is electronically connected to the current detection pin via the corresponding third connector, to receive the current output from the current detection pin.

12. The DC power test system of claim 11, wherein the controller receives the current from each current detection cable to obtains a total current, and adjusts the load of each load cable to make the total current to equal to a predetermined current value.
